(19) United States
(12) Patent Application Publication
(10) Pub. No.: US 2026/0123233 A1
(43) Pub. Date: Apr. 30, 2026

(54) DISPLAY PANEL AND DISPLAY APPARATUS

(71) Applicant: HKC CORPORATION LIMITED, SHENZHEN (CN)

(72) Inventors: Yao LI, SHENZHEN (CN); Lidan YE, SHENZHEN (CN)

(73) Assignee: HKC CORPORATION LIMITED, SHENZHEN (CL)

(21) Appl. No.: 19/369,232

(22) Filed: Oct. 26, 2025

(30) Foreign Application Priority Data
Oct. 31, 2024 (CN) 202411548513.6

(51) Int. Cl. H10K 59/50; H10K 59/122; H10K 59/80

(52) U.S. Cl. CPC H10K 59/50; H10K 59/122; H10K 59/8792

(57) ABSTRACT

A display panel includes: a driver substrate; and a light emitting carrier board, including: a glass substrate, disposed on the driver substrate; and light emitting units, arranged on the glass substrate and electrically connected to the driver circuit layer. The light emitting carrier board includes a color change layer and heating portions. The color change layer is between adjacent light emitting units and contacts an edge of the light emitting unit. The color change layer has a first transmittance rate when a temperature of the light emitting units is less than or equal to a threshold temperature, the heating portions are heated under light irradiation. The color change layer has a second transmittance rate when the temperature of the light emitting units is greater than the threshold temperature, the second transmittance rate is less than the first transmittance rate, and the color change layer blocks the light.

### CROSS REFERENCE TO RELATED APPLICATIONS

The present application claims the priority of the Chinese patent application No. 202411548513.6, filed on Oct. 31, 2024, contents of which are incorporated herein by its entireties.

### TECHNICAL FIELD

Embodiments of the present disclosure relate to the technical field of displaying, and more specifically, to a display panel and a display apparatus.

### BACKGROUND

A monocrystalline silicon driver backplane is a driver substrate which takes a semiconductor device formed based on a complementary metal oxide semiconductor (CMOS) process as a driver unit. Compared to an active-matrix organic light-emitting diode (AMOLED) panel which takes an amorphous silicon, a microcrystalline silicon, or a low-temperature polycrystalline silicon thin-film transistor as the backplane, the monocrystalline silicon driver backplane may have a higher carrier mobility. Therefore, a silicon-based organic light-emitting diode (OLED) display panel may be a best performance display panel to be used in AR/VR products.

Currently, for the silicon-based OLED display panel, an externally-bound display chip may be integrated into the silicon-based driver backplane. A preparation method thereof is to perform evaporation to form the OLED device on the silicon-based driver substrate. Specific processes include: firstly performing deposition to form an anode, then preparing a pixel definition layer, and then performing deposition to successively form an organic light emitting layer and a cathode. In this way, smaller-sized pixel units may be prepared, and displaying finesse even better than retina may be achieved, such that a high resolution, high integration, lower power consumption, a small size, and a light weight, can be achieved.

However, in practice, due to electroluminescent properties and temperature sensitivity of OLED light-emitting materials, a light emitting efficiency of the OLED light-emitting materials may be significantly reduced at low temperatures, brightness may be sharp decreased, such that an entire composite structure may have display anomalies and a low light emitting efficiency. Furthermore, light at edges of light emitting units may not be reflected by anode electrodes and may incident to the silicon-based driver substrate, such that performance of driver components of the silicon-based driver substrate may be abnormal, and drive displaying may be affected.

### SUMMARY

The present disclosure provides a display panel and a display apparatus, so as to solve the technical problem that brightness of a display panel is reduced due to the light emitting efficiency of the OLED light-emitting materials being reduced at low temperatures, and that performance of driver components may be affected due to light being leaked at edges of the light emitting units.

In a first aspect, the present disclosure provides a display panel, including:
a driver substrate, including a silicon substrate and a driver circuit layer arranged on the silicon substrate;
a light emitting carrier board, including:
a glass substrate, disposed on the driver substrate and having a plurality of electrode through holes;
a plurality of light emitting units, arranged into an array and arranged on a side of the glass substrate away from the driver substrate and electrically connected to a driver circuit layer through the plurality of electrode through holes.

The light emitting carrier board further includes a color change layer and a plurality of heating portions; the color change layer is disposed between adjacent light emitting units of the plurality of light emitting units; the color change layer extends along a plane parallel to the glass substrate and contacts an edge of each of the plurality of light emitting units near the glass substrate; the glass substrate defines a plurality of heating through holes; an orthographic projection of the color change layer on the glass substrate covers the plurality of heating through holes; each of the plurality of heating portions fills a respective one of the plurality of heating through holes.

The color change layer has a first transmittance rate when a temperature of the plurality of light emitting units is less than or equal to a threshold temperature, the plurality of heating portions are configured to be heated under irradiation of light passing through the color change layer.

The color change layer has a second transmittance rate when the temperature of the plurality of light emitting units is greater than the threshold temperature, the second transmittance rate is less than the first transmittance rate, and the color change layer is configured to block the light.

In a second aspect, the present disclosure provides a display apparatus, including:
the display panel as described in the above; and
a control circuit board, electrically connected to the display panel and configured to control the display panel to display a corresponding image.

### BRIEF DESCRIPTION OF THE DRAWINGS

In order to more clearly illustrate technical solutions in embodiments of the present disclosure, the accompanying drawings for describing the embodiments will be briefly introduced in the following. Apparently, following description of the accompanying drawings shows only some of the embodiments of the present disclosure, any ordinary skilled person in the art may obtain other accompanying drawings based on the following drawings without making any creative work.

FIG. 1 is a structural schematic view of a display panel according to an embodiment of the present disclosure.

FIG. 2 is a structural planar view of a color change layer and an anode electrode according to an embodiment of the present disclosure.

FIG. 3 is a structural planar view of distribution of heating portions according to an embodiment of the present disclosure.

FIG. 4 is a structural planar view of distribution of heating portions according to another embodiment of the present disclosure.

FIG. 5 is a structural schematic view of the display panel according to a second embodiment of the present disclosure.

FIG. 6 is a structural schematic view of the display panel according to a third embodiment of the present disclosure.

FIG. 7 is a structural schematic view of the display panel according to a fourth embodiment of the present disclosure.

FIG. 8 is a structural schematic view of the display panel according to a fifth embodiment of the present disclosure.

FIG. 9 is a structural schematic view of the display panel according to a sixth embodiment of the present disclosure.

FIG. 10 is a structural schematic view of a display apparatus according to an embodiment of the present disclosure.

### REFERENCE NUMERALS IN THE DRAWINGS

100, display panel; 10, driver substrate; 11, silicon substrate; 12, driver circuit layer; 13, driver electrode; 14, insulating protective layer; 20, light emitting carrier board 21, glass substrate; 211, electrode through hole; 212, heating through hole; 213, conductive portion; 214, auxiliary electrode; 215, connecting electrode; 22, light emitting unit; 221, anode electrode; 222, light emitting layer; 223, cathode electrode; 23, pixel definition layer; 231, pixel opening; 232, function opening; 24, color change layer; 241, first electrode; 242, second electrode; 25, heating portion; 26, temperature sensor; 27, encapsulation layer; 200, control circuit board.

### DETAILED DESCRIPTIONS

The technical solutions in the embodiments of the present disclosure will be clearly and completely described below by referring to the accompanying drawings.

In the following description, for the purpose of illustration and not for the purpose of limitation, specific details such as particular system structures, interfaces, and techniques, are provided for thoroughly understanding the present disclosure.

The technical solutions in the embodiments of the present disclosure will be clearly and completely described below by referring to the accompanying drawings in the embodiments of the present disclosure. Apparently, the described embodiments are only a part of, not all of, the embodiments of the present disclosure. All other embodiments, which are obtained by any ordinary skilled person in the art based on the embodiments in the present disclosure without making creative work, shall fall within the scope of the present disclosure.

Terms “first”, “second”, and “third” in the present disclosure are used for descriptive purposes only and are not to indicate or imply relative importance or implicitly specifying the number of technical features. Therefore, a feature defined with “first”, “second”, “third” may include at least one such feature, either explicitly or implicitly. In the description of the present disclosure, “a plurality of” means at least two, such as two, three, and so on, unless otherwise expressly and specifically limited. All directional indications (such as up, down, left, right, front, rear . . . ) in the embodiments of the present disclosure are only used to explain a relative positional relationship and movement between components at a particular attitude (the attitude as shown in the accompanying drawings). The directional indication may be changed accordingly when the particular attitude is changed. Furthermore, terms “include” and “have” and any variations thereof are intended to cover non-exclusive inclusion. For example, a process, a method, a system, a product or an apparatus including a series of steps or units is not limited to the listed steps or units, but may further include steps or units that are not listed or steps or units that are inherently included in the process, the method, the system, the product or the apparatus.

Reference to “embodiments” herein means that particular features, structures, or characteristics described in an embodiment may be included in at least one embodiment of the present disclosure. The phrase at various sections in the specification does not necessarily refer to one same embodiment, nor separate or alternative embodiments that are mutually exclusive of other embodiments. Any ordinary skilled person in the art shall understand that, both explicitly and implicitly, the embodiments described herein may be combined with other embodiments.

The present disclosure will be described in detail by referring to drawings and embodiments.

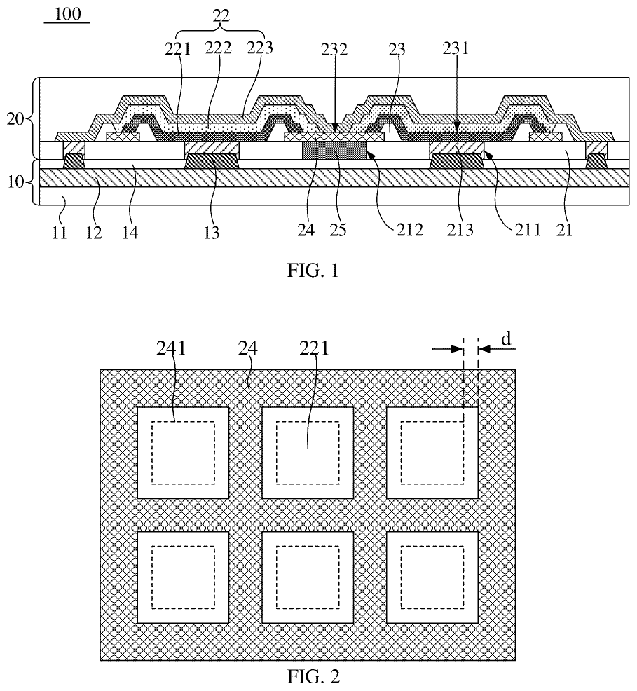

As shown in FIG. 1, FIG. 1 is a structural schematic view of a display panel according to an embodiment of the present disclosure. In the present embodiment, a display panel 100 is provided, the display panel 100 may include a driver substrate 10 and a light emitting carrier board 20. The driver substrate 10 may be disposed corresponding to the light emitting carrier board 20 and electrically connected to the light emitting carrier board 20 to drive the light emitting carrier board 20 to display an image.

The driver substrate 10 may include a silicon substrate 11 and a driver circuit layer 12 arranged on the silicon substrate 11.

The silicon substrate 11 may carry the driver circuit layer 12 and a plurality of film layers and components. In some embodiments, the silicon substrate 11 may be configured as a monocrystalline silicon substrate.

The driver circuit layer 12 may include a plurality of pixel driver circuits (not shown in the drawings). Each of the plurality of pixel driver circuits may include a semiconductor driver member. In some embodiments, a CMOS member may serve as the semiconductor driver member. The CMOS member and other associated member may cooperatively form the pixel driver circuit to drive the light emitting carrier board 20 to emit light.

In some embodiments, the driver substrate 10 may further include a plurality of driver electrodes 13 and an insulating protective layer 14.

The plurality of driver electrodes 13 may be arranged on a side of the driver circuit layer 12 away from the silicon substrate 11. The plurality of driver electrodes 13 may be electrically connected to the plurality of pixel driver circuits respectively and a power supply signal, so as to transmit corresponding drive signals to the light emitting carrier board 20. It should be noted that, in the display panel 100, the power supply signal may usually include a direct current power supply signal required to drive the light emitting carrier board 20 to emit light, such as a VDD signal, a VSS signal, and so on. In the present embodiment, the power supply signal connected to a plurality of light emitting units 22 of the light emitting carrier board 20 may be a cathode drive signal (usually the VSS signal).

The insulating protective layer 14 may be arranged on a side of the driver circuit layer 12 away from the silicon substrate 11. A plurality of holes may be defined in the insulating protective layer 14. The plurality of holes are arranged in correspondence with the plurality of driver electrodes 13, such that the plurality of driver electrodes 13 are exposed. That is, orthographic projections of the plurality of holes defined in the insulating protective layer 14 onto the driver circuit layer 12 may coincide correspondingly with orthographic projections of the plurality of driver electrodes 13 onto the driver circuit layer 12. In this way, the plurality of holes may directly face the plurality of driver electrodes 13, respectively, and the plurality of driver electrodes 13 may be exposed to be aligned and bonded with the driver substrate 10 to form electrical connection with the driver substrate 10, such that signal connection may be achieved. Specifically, the insulating protective layer 14 may include an organic insulating layer and/or an inorganic insulating layer. The insulating protective layer 14 may be specifically configured as the inorganic insulating layer, and a material of the inorganic insulating layer may be specifically an inorganic insulating material, such as silicon dioxide, silicon nitride, silicon nitride oxide, and the like.

The light emitting carrier board 20 may include a glass substrate 21 and a plurality of light emitting units 22 arranged on a side of the glass substrate 21 away from the driver substrate 10.

The glass substrate 21 may be arranged on the driver substrate 10, and the glass substrate 21 may define a plurality of electrode through holes 211. The plurality of electrode through holes 211 may be disposed in alignment to the plurality of driver electrodes 13. That is, orthographic projections of the plurality of electrode through holes 211 on the driver substrate 10 may coincide with the plurality of driver electrodes 13 on the driver substrate 10. In this way, each of the plurality of light emitting units 22 may be electrically connected to a respective one of the plurality of driver electrodes 13 through a respective one the plurality of electrode through holes 211. Specifically, in some embodiments, each of the plurality of electrode through holes 211 may be filled with a conductive portion 213. Two opposite sides of the conductive portion 213 in a thickness direction of the glass substrate 21 may be respectively electrically connected to one respective light emitting unit 22 one respective driver electrode 13, such that connection of the drive signal may be achieved. Specifically, on a plane parallel to the glass substrate 21, each of the plurality of electrode through holes 211 may be a circular through hole or a rectangular through hole, or a polygonal through hole, or an elliptical through hole, and so on. In the thickness direction of the glass substrate 21, the electrode through hole 211 may be a conical through hole or a straight through hole or a double-sided trumpet-shaped hole having a small center and two large ends. A shape of the electrode through hole 211 may be determined according to actual demands to meet requirements for signal transmission and production processes.

The plurality of light emitting units 22 may be arranged in an array and on the side of the glass substrate 21 away from the driver substrate 10. Each of the plurality of light emitting units 22 may be electrically connected to the driver circuit layer 12 through a respective one of the plurality of electrode through holes 211. Orthographic projections of the plurality of light emitting units 22 on the glass substrate 21 may overlap the plurality of electrode through holes 211, such that each of the plurality of light emitting units 22 may contact the respective conductive portion 213 to form electrical connection. In this way, the plurality of light emitting units 22 may form electrical connection with the driver circuit layer 12 to achieve connection of the drive signal.

According to the above embodiment, the glass substrate 21 may be disposed between the driver substrate 10 and the plurality of light emitting units 22. Therefore, the plurality of light emitting units 22 may be prepared on the glass substrate 21, and the glass substrate 21 may protect the driver circuit layer 12 on the driver substrate 10. In this way, an influence and damage to the driver circuit layer 12 caused by directly preparing the plurality of light emitting units 22 on the driver substrate 10 may be avoided, and a product yield may be improved. By defining the plurality of electrode through holes 211 in the glass substrate 21, the plurality of light emitting unit 22 may be electrically connected to the driver circuit layer 12 on the driver substrate 10 through the plurality of electrode through holes 211 respectively, such that signal connection may be achieved. In this way, the drive signal of the driver substrate 10 may be transmitted to the plurality of light emitting units 22 to drive the plurality of light emitting units 22 to emit light and display a corresponding image.

Moreover, by configuring the glass substrate 21 as a substrate for the light emitting carrier board 20, compared to configuring a silicon substrate as the substrate, the glass substrate 21 may have ideal insulating performance, such that an oxidized insulating layer may not be arranged on a hole wall of the electrode through hole 211 of the glass substrate 21, and a holding technology for thin wafers may not be applied. Therefore, costs may be reduced. In addition, the glass substrate 21 may have a lower cost than the silicon substrate, costs may further be reduced. Moreover, due to the ideal insulating performance of the glass substrate 21, an electromagnetic coupling effect may not be generated during transmitting signals, an insertion loss of signals, crosstalk, and other problems May be reduced, and integrity of signals may be ensured. Further, by preparing the plurality of light emitting units 22 on the glass substrate 21, a large-sized light emitting carrier board 20 may be achieved more easily. Furthermore, by arranging the plurality of light emitting units 22 on the glass substrate 21 to form the light emitting carrier board 20, the driver substrate 10 and the light emitting carrier board 20 may be separately prepared, a preparation time length of the display panel 100 may be shortened, a production cycle may be improved.

In the thickness direction of the glass substrate 21, each of the plurality of light emitting units 22 may include an anode electrode 221, a light emitting layer 222, and a cathode electrode 223 that are sequentially stacked in a direction away from the glass substrate 21. An orthographic projection of the anode electrode 221 may cover a respective one of the plurality of electrode through holes 211, such that the anode electrode 221 may contact with one respective conductive portion 213 to form electrical connection. Cathode electrodes 223 of the plurality of light emitting units 22 may be electrically connected to each other and may be electrically connected to corresponding driver electrodes 13 on the driver substrate 10 through a portion of the plurality of electrode through holes 211 located at an edge region of the glass substrate 21. Specifically, the cathode electrodes 223 may be electrically connected to the corresponding driver electrodes 13 through conductive portions 213 received in the portion of the plurality of electrode through holes 211. In some embodiments, the plurality of light emitting units 22 may include a first light emitting unit 22, a second light emitting unit 22, and a third light emitting unit 22, that emit light in different colors, such as a red light emitting unit 22, a green light emitting unit 22, and a blue light emitting unit 22, such that color displaying may be achieved. Specifically, the color of the light of each of the plurality of light emitting units 22 may be determined by a color of light emitted from the light emitting layer 222. Alternatively, in some other embodiments, the plurality of light emitting units 22 may emit light in a same color, such as white, red, green, blue, or any other color, which may be determined according to the actual needs. For example, the plurality of light emitting units 22 may be white light emitting units 22. Grayscale displaying may be achieved by controlling brightness of the plurality of light emitting units 22. A color resistant layer may be arranged above the plurality of light emitting units 22 to achieve color displaying. Each of the plurality of light emitting units 22 may be a current-driven light-emitting element, such as an organic light emitting diode (OLED), a light emitting diode (LED), a mini light emitting diode (Mini-LED), and a micro light-emitting diode (Micro-LED). The present embodiment will be described based on an example where the light emitting unit 22 is the OLED.

Compared to a semiconductor driver member on the silicon-based driver substrate 10, due to light emitting performance of a material of the OLED light emitting layer 222 being temperature sensitive, a light emitting efficiency may be significantly reduced at low temperatures, resulting in a dramatic decrease in brightness, such that the display panel 100 may have display abnormality and a lowered light emitting efficiency. Moreover, in the plurality of OLED light emitting units 22, since light emitted at edges of the plurality of light emitting units 22 may not be reflected reversely by anodes, the light may directly irradiate into the driver circuit layer 12, causing the semiconductor driver member to operate abnormally, resulting in the display panel 100 displaying abnormality.

In order to solve the above technical problems, in the present embodiment, the light emitting carrier board 20 may further include a color change layer 24 and a plurality of heating portions 25. The color change layer 24 may be disposed between adjacent two of the plurality of light emitting units 22 and may extend along a plane parallel to the glass substrate 21 and may contact a side edge of each light emitting unit 22 near the glass substrate 21. The glass substrate 21 may define a plurality of heating through holes 212, and an orthographic projection of the color change layer 24 on the glass substrate 21 may cover the plurality of heating through holes 212. Each of the plurality of heating portion 25 may fill in a respective one of the plurality of heating through holes 212.

The color change layer 24 may change a state under a specific triggering condition. A transmittance rate of light of the color change layer 24 may be different in different states. Therefore, by controlling the state of the color change layer 24, when the transmittance rate of the color change layer 24 is low, the color change layer 24 may shield the light at the edge of the light emitting unit 22. Each of the plurality of heating portions 25 may be heated under ambient light. Therefore, the plurality of heating portion 25 may be disposed below the color change layer 24. When a temperature is excessively low resulting in a significant decrease in the light emitting efficiency of the plurality of light emitting units 22, the plurality of heating portions 25 may cooperate with the color change layer 24. The transmittance rate of the color change layer 24 may be increased by controlling the state of the color change layer 24, such that external light and the light from the plurality of light emitting units 22 may be irradiated to the plurality of heating portions 25 through the color change layer 24. In this way, the plurality of heating portion 25 may be heated under the light, so as to heat surrounding light emitting units 22, such that the temperature of the plurality of light emitting units 22 may be increased, reduction in the light emitting efficiency of the plurality of light emitting units 22 at low temperatures may be reduced or avoided.

Specifically, when the temperature of the light emitting unit 22 is less than or equal to a threshold temperature, the color change layer 24 may have a first transmittance rate, and the plurality of heating portions 25 may be heated under irradiation of light passing through the color change layer 24. When the temperature of the light emitting unit 22 is greater than the threshold temperature, the color change layer 24 may have a second transmittance rate, and the second transmittance rate may be less than the first transmittance rate for blocking light.

When the temperature of the light emitting unit 22 is less than or equal to the threshold temperature, the light emitting efficiency of the light emitting unit 22 may be decreased significantly. At this moment, the color change layer 24 can be made to be in a first state according to properties of the color change layer 24. In the first state, the color change layer 24 may have the higher first transmittance rate, such that the light at the edge of the light emitting unit 22 and the external light may be irradiated through the color change layer 24 to the heating portion 25. The heating portion 25 may be heated under the light, such that the heating portion 25 may heat up the light emitting units 22 surrounding and adjacent to the heating portion 25, such that the temperature of the light emitting unit 22 may be increased. In this way, reduction in the light emitting efficiency of the light emitting units 22 at low temperatures may be solved, and a decreased in brightness of the display panel 100 and abnormal displaying at low temperatures may be solved. Furthermore, due to the optical-thermal conversion effect of the heating portion 25, the light irradiated to the driver circuit layer 12 may be reduced, such that abnormal performance of the semiconductor driver member due to light leakage from the light emitting units 22 may be solved.

When the temperature of the light emitting unit 22 is greater than the threshold temperature, the color change layer 24 may be changed to a second state according to the properties of the color change layer 24. In the second state, the color change layer 24 may have the lower second transmittance rate, such that at least a majority of the light may be blocked by the color change layer 24, abnormal performance of the semiconductor driver member in the driver circuit layer 12 due to light irradiation may be reduced.

In an embodiment, the threshold temperature may be a temperature at which the light emitting efficiency of the light emitting unit 22 decreases by a %, and the a % may be in a range of 5% to 40%. For example, the a % may be 20%. That is, when the light emitting efficiency of the light emitting unit 22 decreases by 20%, i.e., the light emitting efficiency of the light emitting unit 22 may be 80% of an original light emitting efficiency, a temperature at this moment may be the threshold temperature, and the temperature may be obtained by testing experiments. Specifically, the threshold temperature may be in a range of −40° C. to 0° C. For example, the threshold temperature may be −25° C. When the temperature of the light emitting unit 22 in contact with the color change layer 24 is higher than −25° C. the color change layer 24 may be in the second state, having the second transmittance rate. At least a large portion of the light at the edge of the light emitting unit 22 may be blocked by the color change layer 24 and may not pass through the color change layer 24, i.e., the color change layer 24 may shield light. When the temperature of the light emitting unit 22 in contact with the color change layer 24 is lower than −25° C., the color change layer 24 may be in the first state, having the first transmittance rate. The light at the edge of the light emitting unit 22 may pass through the color change layer 24 to irradiate the heating portion, such that the heating portion 25 may be heated up under the light irradiation to heat the light emitting unit 22, and to improve the light emitting efficiency of the light emitting unit 22.

As shown in FIG. 1, in the present embodiment, the light emitting carrier board 20 may further include a pixel definition layer 23 arranged on the glass substrate 21. The pixel definition layer 23 may have a plurality of pixel openings 231 that are in one-to-one correspondence with the plurality of light emitting units 22. Orthographic projections of the plurality of pixel openings 231 on the glass substrate 21 may cover the plurality of electrode through holes 211. In each of the plurality of pixel openings 231, the anode electrode 221, the light emitting layer 222 and the cathode electrode 223 may be stacked to form a respective one of the plurality of light emitting units 22 as described above. The pixel definition layer 23 may be configured to separate the anode electrode 221 and the light emitting layer 222 of one of the plurality of light emitting units 22 from the anode electrode 221 and the light emitting layer 222 of another one of the plurality of light emitting units 22, such that color crosstalk between different ones of the plurality of light emitting units 22 may be prevented. The anode electrode 221 may be electrically connected to the driver circuit layer 12 through the respective electrode through hole 211. Adjacent cathode electrodes 223 may be connected to each other and may extend to the edge region of the glass substrate 21 to be electrically connected to the driver circuit layer 12 through the portion of the plurality of electrode through holes 211 located at the edge region of the glass substrate 21.

The color change layer 24 may be disposed between adjacent pixel openings 231 and may extend along the plane parallel to the glass substrate 21 and may contact and overlap with a side edge of the anode electrode 221 near the glass substrate 21.

In the present embodiment, the pixel definition layer 23 may define a function opening 232, the function opening 232 may expose at least a portion of the color change layer 24. The anode electrode 221 may extend out of the respective pixel opening 231 and extend into the function opening 232 to contact and overlap with the exposed portion of the color change layer 24. The anode electrode 221 may be spaced apart from the cathode electrode 223 by the light emitting layer 222. That is, an orthographic projection of the anode electrode 221 on the glass substrate 21 may cover an orthographic projection of the respective pixel opening 231 on the glass substrate 21, and the edge of the anode electrode 221 may extend into the function opening 232 and cover and contact a surface of the color change layer 24 away from the glass substrate 21. An orthographic projection of the light emitting layer 222 on the glass substrate 21 may cover the orthographic projection of the anode electrode 221 on the glass substrate 21. An edge of the light emitting layer 222 may exceed the anode electrode 221 in the plane parallel to the glass substrate 21 and may cover and contact the surface of the color change layer 24 away from the glass substrate 21. The cathode electrode 223 may cover a side of the light emitting layer 222 away from the glass substrate 21 and cover the exposed portion of the color change layer 24.

According to the above embodiment, the edge of the light emitting unit 22 may directly cover the surface of the color change layer 24 away from the glass substrate 21, i.e., the color change layer 24 may extend to a position below the edge of the light emitting unit 22 and is in contact with the edge of the light emitting unit 22. In this way, the light from the edge of the light emitting unit 22 may directly incident into the light emitting layer 222, in order to reduce light leakage and to improve a light shielding effect of the color change layer 24.

Specifically, a thickness of the color change layer 24 in the thickness direction of the glass substrate 21 may be 2000 Å to 3000 Å, such as 2000 Å, 2100 Å, 2200 Å, 2300 Å, 2400 Å, 2500 Å, 2600 Å, 2700 Å, 2800 Å, 2900 Å, or 3000 Å. The specific thickness may be determined according to a thickness of the pixel definition layer 23 and requirements for the transmittance rate, enabling the color change layer 24 to meet requirements for constructional coordination with adjacent film layers and requirements for the transmittance rate of the color change layer 24 in various states.

As shown in FIG. 2, FIG. 2 is a structural planar view of the color change layer and the anode electrode according to an embodiment of the present disclosure. In an embodiment, the color change layer 24 may have a plurality of hollow portions in one-to-one correspondence with the plurality of light emitting units 22. The plurality of light emitting units 22 may be disposed at positions respectively corresponding to the plurality of hollow portions. The edge of each light emitting unit 22 may extend out of the respective hollow portion to overlap with the color change layer 24. A width of an overlapping portion between the color change layer 24 and the anode electrode 221 may be in a range of 0.5 μm to 1.5 μm. That is, the color change layer 24 may be configured in a form of a grid and may have the plurality of hollow portions in one-to-one correspondence with the plurality of light emitting units 22; and the orthographic projections of the plurality of light emitting units 22 on the glass substrate 21 may cover orthographic projections of the plurality of hollow portions on the glass substrate 21. Specifically, the orthographic projection of the anode electrode 221 of each light emitting unit 22 on the glass substrate 21 may cover the orthographic projection of the respective hollow portion on the glass substrate 21. The edge of the anode electrode 221 may be overlapping arranged on a portion of the color change layer 24 located surrounding the respective hollow portion. The width of the overlapping portion may be in a range of 0.5 μm to 1.5 μm. That is, the overlapping portion (intersecting portion) of the anode electrode 221 and the color change layer 24 may be annular. A width of the annulus may be in a range of 0.5 μm to 1.5 μm. It may be ensured that the light at the edge of the light emitting unit 22 may all be incident into the color change layer 24, ensuring the light shielding effect of the color change layer 24, avoiding or reducing the light leakage, further avoiding or reducing a possibility of the light at the edge of the light emitting unit 22 entering the driver circuit layer 12. To be noted that the light at the edge of the light emitting unit 22 may specifically include the ambient light incident to the edge of the light emitting unit 22 and light emitted by the light emitting unit 22 itself at the edge of the light emitting unit 22.

In the present embodiment, a material of the color change layer 24 may be a thermochromic material. When the temperature is less than or equal to the threshold temperature, the first transmittance rate may be 80% to 100%. When the temperature is greater than the threshold temperature, the second transmittance rate may be 0 to 80%. As the temperature increases, a rate of decrease in the second transmittance rate gradually increases. It can be understood that the specific trigger condition for changing the state of the color change layer 24 may be the temperature. When the temperature is less than or equal to the threshold temperature, the color change layer 24 switches to the first state having the first transmittance rate; and when the temperature is greater than the threshold temperature, the color change layer 24 switches to the second state having the second transmittance rate.

The thermochromic material may be a material that may change optical properties (such as color, transparency, and reflectivity) as temperature changes. Changes in the optical properties may be usually reversible, when the temperature is increased or decreased to a specific threshold value, the optical properties may be changed. Specifically, the thermochromic material may include thermochromic Calcium titanium that may have tunable properties, fast response, and effective light modulation. The material of the color change layer 24 in present embodiment may be the thermochromic calcium titanium, such that the color change layer 24 may have following properties. When the ambient temperature of the color change layer 24≤the threshold temperature, the color change layer 24 may have the first transmittance rate, and the first transmittance rate may be 80% to 100%. When the ambient temperature of the color change layer 24>the threshold temperature, the color change layer 24 may have the second transmittance rate, and the second transmittance rate may be 0 to 80%. When the threshold temperature<the ambient temperature of the color change layer 24≤a boundary temperature, the color change layer 24 may have the second transmittance rate, and the second transmittance rate may be 0 to 80%, and the transmittance rate may decrease rapidly as the temperature increases. That is, a decrease rate of the second transmittance rate gradually increases as the temperature increases. When the ambient temperature of the color change layer 24>the boundary temperature, the second transmittance rate of the color change layer 24 may be close to 0. Specifically, the threshold temperature may be in a range of −40° C. to 0° C., and the boundary temperature may be in a range of 20° C. to 30° C.

Specifically, since the plurality of light emitting units 22 are adjacent to and in contact with the color change layer 24, the temperature of the plurality of light emitting units 22 may be the ambient temperature of the color change layer 24. In an example, the threshold temperature may be 0° C., and the boundary temperature may be 25° C. When the temperature of the plurality of light emitting units 22≤0° C., the transmittance rate of the color change layer 24 may be in a range of 80% to 100%, such that light at edges of the plurality of light emitting units 22 may enter the plurality of heating portions 25 through the color change layer 24, and the plurality of heating portions 25 may be heated by the light irradiation so as to heat the plurality of light emitting units 22 to improve the light emitting efficiency of the plurality of light emitting units 22. When 0° C.<the temperature of the plurality of light emitting units 22≤25° C., the transmittance rate of the color change layer 24 may be in a range of 0 to 80%, and the transmittance rate decreases rapidly as the temperature increases. That is, the decrease rate of second transmittance rate increases gradually as the temperature increases, such that the color change layer 24 may block at least a portion of the light, and the light shielding effect of the color change layer 24 may be rapidly improved as the temperature increases. When the temperature of the plurality of light emitting unit 22s>25° C., the transmittance rate of the color change layer 24 may be close to 0, such that the light shielding effect of the color change layer 24 may be optimized, and the light around the light emitting unit 22 may be almost entirely blocked by the color change layer 24, such that the light may not enter the driver circuit layer 12. By configuring the thermochromic material as the color change layer 24, the color change layer 24 may switch the state and the transmittance rate automatically according to the temperature of the plurality of light emitting units 22. A control component for controlling the state of the color change layer 24 may not be arranged, simplifying a structure of the display panel 100 and a heating control method.

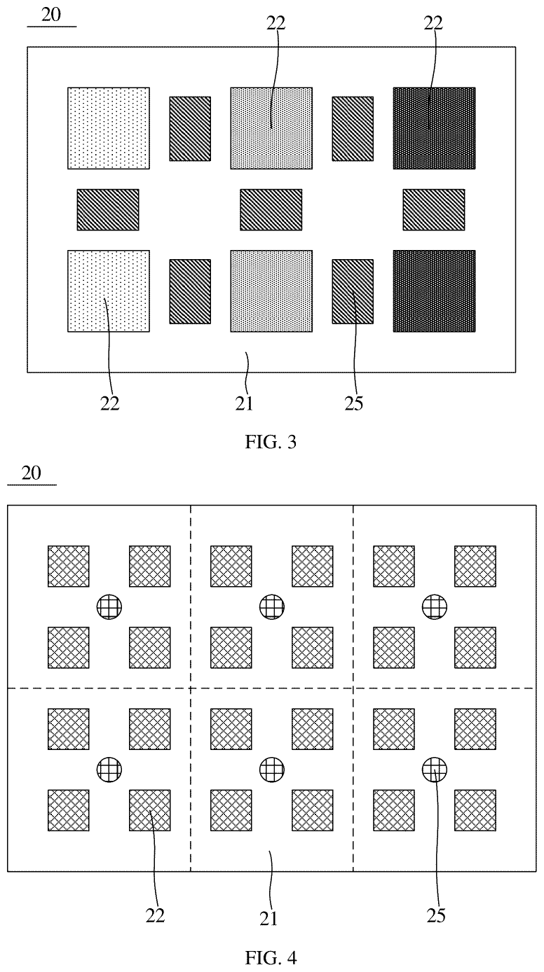

As shown in FIG. 3, FIG. 3 is a structural planar view of distribution of heating portions according to an embodiment of the present disclosure. In the present embodiment, each of the plurality of heating portions 25 may be disposed between adjacent two of the plurality of light emitting units 22 and may be filled in the respective heating through hole 212 of the glass substrate 21. Specifically, the heating portion 25 may be disposed between every two adjacent light emitting units 22. In this way, a periphery of each light emitting unit 22 may be arranged with the heating portion 25, such that heating may be performed in a more targeted manner, localized heating may be achieved, a heating efficiency and a heating effect may be achieved. Furthermore, since the periphery of each light emitting unit 22 may be arranged with the heating portion 25, the optical-thermal conversion by the heating portion 25 may further reduce the light incident into the driver circuit layer 12 and reduce the influence, caused by the light leakage, on the performance of the semiconductor element.

According to arrangement of the plurality of heating portions 25, each of the plurality of heating through holes 212 may be defined in the glass substrate 21 between every adjacent two electrode through holes 211; and a spacing between the heating through hole 212 and one of the adjacent two electrode through holes 211 may be not less than 2 μm. To be noted that, the expression “the spacing between the heating through hole 212 and one of the adjacent two electrode through holes 211” refers to the spacing between the heating through hole 212 and one of the plurality of electrode through holes 211 that is closest to the instant heating through hole 212. For the spacing, on a line connected between a center axis of the heating through hole 212 and a center axis of the closest electrode through hole 211, an intersection A is formed by the electrode through hole 211 intersecting with the line, and an intersection B is formed by the heating through hole 212 intersecting with the line, and a distance AB between the intersection A and the intersection B may be the spacing between the heating through hole 212 and the adjacent electrode through hole 211.

Specifically, while it is ensured that the spacing between the heating through hole 212 and the adjacent electrode through hole 211 is not less than 2 μm, a diameter of the electrode through hole 211 and a diameter of the heating through hole 212 may be determined according to the actual need. In an embodiment, the diameter of the electrode through holes 211 and the diameter of the heating through hole 212 may be determined according to a hole punching process. For example, in the case of limited space, the diameter of the electrode through hole 211 may be determined in priority, and the diameter of the heating through hole 212 may be appropriately reduced. In this way, stability of connection of the drive signal and strength of the glass substrate 21 may be ensured.

In the present embodiment, a material of the plurality of heating portions 25 may be high entropy ceramic. The high entropy ceramic may be similar to high entropy alloys and may be solid solutions formed from five or more ceramic group elements having high resistive state entropy. The high entropy ceramic may include various types of materials, including, such as, high entropy oxides (HEOs), high entropy nitrides (HENs), high entropy carbides (HECs), high entropy borides (HEBs), high entropy hydrides (HEHs), high entropy silicides (HEIs), high entropy sulfides (HESs), high entropy fluorides (HEFs), high entropy phosphides (HEPs), high entropy phosphates (HEPO4s), and high entropy nitrogen oxides (HEON), high entropy carbon nitrides (HECN) and high entropy boron carbon nitrides (HEBCN). The high entropy ceramic may be extremely stable and may remain in a single phase under extreme temperatures, pressures, and chemical environments. The high entropy ceramic may be synthesized at high temperatures and quenched and stabilized at the room temperature, and may be resistant to corrosion. Furthermore, the high entropy conductive ceramic material may have strong optical effects under light irradiation and may be rapidly heated up and dissipate heat, and may be transformed from an insulator to a conductor.

Each heating through hole 212 may be filled with the high entropy ceramic material to form the heating portion 25. The heating portion 25 formed by the high entropy ceramic material can be rapidly heated up and generate heat under light irradiation. Furthermore, the heating portion 25 may be received in the heating through hole 212 of the glass substrate 21. Since the glass substrate 21 may have better thermal conductivity, after the heating portion 25 is locally heated up and generates heat, the heating portion 25 may rapidly conduct the generated heat to a surrounding region through the glass substrate 21, so as to heat the light emitting layer 222. A better heating effect may be achieved. The glass substrate 21 may be thermally stable, i.e., the glass substrate 21 may rapidly conduct heat, such that after localized temperature increases, rapid decrease in the transmittance rate of the color change layer 24, caused by the heat being unable to be transferred rapidly, may be avoided. Since a space of blanked regions of the glass substrate 21 may be larger than a space of blanked region of a film layer where light emitting units 22 and the pixel definition layer 23 are arranged above the glass substrate 21, requirements for a volume and an area for the plurality of heating portions 25 may be met, and a heating effect may be improved.

As shown in FIG. 4, FIG. 4 is a structural planar view of distribution of heating portions according to another embodiment of the present disclosure. Different from the embodiment shown in FIG. 3, in the present embodiment, the light emitting carrier board 20 may be divided into a plurality of heating zones that are spliced to each other. At least two light emitting units 22 and at least one heating portion 25 may be arranged in each of the plurality of heating zones. The at least one heating portion 25 may be uniformly distributed in each heating zone.

It is to be understood that the plurality of light emitting units 22 may be divided based on the plurality of heating zones that are spliced to each other and divided into the plurality of heating zones. In each of the plurality of heating zone, m rows and n columns (m*n) of light emitting units 22 of the plurality of light emitting units 22 are arranged. Each of the m and the n may be a positive integer, and m*n may be a positive integer greater than or equal to 2. At least one heating portion 25 may be arranged in each heating zone to heat the m*n light emitting units 22 in the heating zone. For example, in an example, 2*2 light emitting units 22 may be arranged in each heating zone, one heating portion 25 is arranged, and the heating portion 25 may be located at a center of the heating zone. In this way, the heating portion 25 has an equal distance to a center of each of the 2*2 light emitting units 22 in the heating zone, such that the heating portion 25 may transfer an equal amount of heat to each of the 2*2 light emitting units 22. In another example, m*n light emitting units 22 may be arranged in each of the plurality of heating zones. Each of the m and the n is greater than or equal to 3. More than one (at least two) of the plurality of heating portions 25 may be arranged in each of the plurality of heating zones. The more than one heating portions 25 may be uniformly distributed in the heating zone to ensure a heating rate for each of the m*n light emitting units 22 and ensure an equal amount of heat to be transferred to each of the m*n light emitting units 22. Specifically, the plurality of heating zones may have the same number of heating portions 25 or different numbers of heating portions 25. The number of heating portions 25 in each of the plurality of heating zones may be determined based on an area of each of the plurality of heating zones, the number of light emitting units 22 in each of the plurality of heating zones, and a heating demand, which will not be limited herein.

In the present embodiment, by dividing the light emitting carrier board 20 into the plurality of heating zones, and distribution and the number of heating portions 25 in each heating zone may be determined according to characteristics of each heating zone, such that arrangement of the plurality of heating portions 25 may be determined in a more targeted manner, and an overall heating effect of the light emitting carrier board 20 may be better. Furthermore, by arranging the plurality of heating portions 25 based on the plurality of heating zones, the number of the plurality of heating through holes 212 on the glass substrate 21 may be appropriately reduced, such that structural strength of the glass substrate 21 may be improved, the amount of the material of the plurality of heating portions 25 may be reduced, and costs may be reduced.

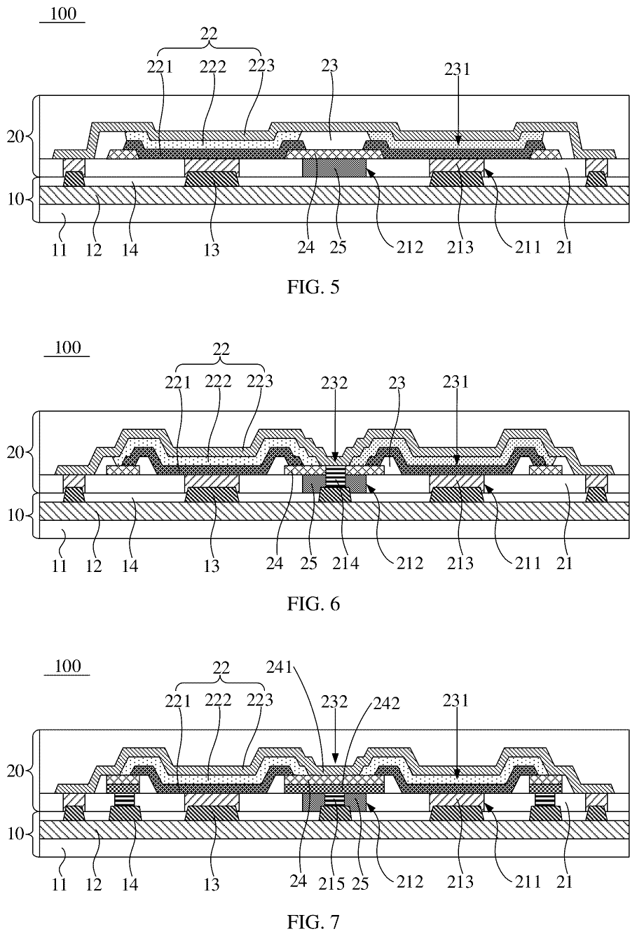

As shown in FIG. 5, FIG. 5 is a structural schematic view of the display panel according to a second embodiment of the present disclosure. In the present embodiment, the anode electrode 221 may extend to the edge of the color change layer 24 and may contact with and overlap with the side of the edge of the color change layer 24 away from the glass substrate 21. The pixel definition layer 23 may be disposed on the side of the color change layer 24 away from the glass substrate 21, and the pixel opening 231 may expose the anode electrode 221.

Specifically, the edge of the anode electrode 221 may be overlapped on the color change layer 24, and the edge of the anode electrode 221 may be disposed between the pixel definition layer 23 and the color change layer 24. Being different from the embodiment of FIG. 1, in the present embodiment, the pixel definition layer 23 may be prepared after the anode electrode 221 is formed. The pixel definition layer 23 may define a plurality of pixel openings 231, the plurality of pixel openings 231 may be in one-to-one correspondence to anode electrodes 221 of the plurality of light emitting units, and each of the plurality of pixel openings 231 may expose one anode electrode 221.

According to the above configuration, the pixel definition layer 23 may not define any function opening 232, i.e., a new mask plate may not be needed to perform a patterning process to form the pixel definition layer 23 having the function opening 232. Furthermore, A side surface of the pixel definition layer 23 away from the color change layer 24 may be flatter, facilitating connection between adjacent cathode electrodes 223, preventing disconnection of the cathode electrodes 223, during evaporation, at a position of the function opening 232 defined in the pixel definition layer 23. In addition, by overlapping the color change layer 24 with the edge of the anode electrode 221, light at the edge of the light emitting unit 22 may enter the color change layer 24, such that the light shielding effect may be achieved; and, at low temperatures, the color change layer 24 and the plurality of heating portions 25 may cooperatively achieve the above heating function for the plurality of light emitting units 22.

As shown in FIG. 6, FIG. 6 is a structural schematic view of the display panel according to a third embodiment of the present disclosure. In the present embodiment, the light emitting carrier board 20 may further include an auxiliary electrode 214. The auxiliary electrode 214 may extend through the heating portion 25, the color change layer 24, and the pixel definition layer 23 along the thickness direction of the glass substrate 21. The auxiliary electrode 214 may contact the cathode electrode 223 to form electrical connection. A side of the auxiliary electrode 214 near the driver substrate 10 may be electrically connected to the driver circuit layer 12.

Specifically, the auxiliary electrode 214 may extend through the heating portion 25, the color change layer 24, and the pixel definition layer 23 to contact and to be electrically connected with the cathode electrode 223. The side of the auxiliary electrode 214 near the driver substrate 10 may be electrically connected to the driver circuit layer 12. Specifically, the side of the auxiliary electrode 214 may be connected to the cathode drive signal in the driver circuit layer 12, such that the auxiliary electrode 214 may serve as a signal source for the cathode electrode 223, signal homogeneity of the cathode electrode 223 may be improved. Furthermore, by using the high entropy ceramic as the material of the plurality of heating portions 25, when the plurality of heating portions 25 are being heated, the plurality of heating portions 25 made of the high entropy ceramic may be converted into the conductor at high temperatures to be electrically connected with the auxiliary electrode 214, further improving signal stability of the cathode electrode 223.

Specifically, the auxiliary electrode 214 serves as an auxiliary connection to the cathode. Therefore, a diameter of a via hole in which the auxiliary electrode 214 may be filled and arranged may be smaller, such that the auxiliary electrode 214 may not affect functions and effects of the plurality of heating portions 25 and the color change layer 24. Further, a plurality of auxiliary electrodes 214 may be arranged in only a portion of the plurality of heating portions 25. The plurality of auxiliary electrodes 214 may be evenly distributed across an overall region formed by the cathode electrodes 223, so as to ensure the signal homogeneity of the cathode electrode 223. The number of the plurality of auxiliary electrodes 214 may be determined according to an area of a displaying region of the light emitting carrier board 20 and distribution of the signal of the cathode electrode 223, which will not be limited herein.

As shown in FIG. 7, FIG. 7 is a structural schematic view of the display panel according to a fourth embodiment of the present disclosure. In the present embodiment, the material of the color change layer 24 may be an electrochromic material, such that the color change layer 24, when being subjected to an applied electric field, may undergo stable and reversible color change and transparency change.

In the present embodiment, the pixel definition layer 23 may define a function opening 232 that may expose at least a portion of the color change layer 24. The anode electrode 221 may extend out of the pixel opening 231 and extend into the function opening 232 to contact and overlap with the color change layer 24. The anode electrode 221 may be spaced apart from the cathode electrode 223 by the light emitting layer 222. Further, the cathode electrode 223 may extend into the function opening 232 to contact the color change layer 24 to further serve as a first electrode 241 of the color change layer 24. A side of the color change layer 24 near the glass substrate 21 may be arranged with a second electrode 242. That is, in the direction perpendicular to the glass substrate 21, two opposite sides of the color change layer 24 may be respectively arranged with the cathode electrode 223 and the second electrode 242. The cathode electrode 223 may further serve as the first electrode 241 of the color change layer 24, such that the cathode electrode 223 and the second electrode 242 cooperatively generate an applied electric field configured to control the state of the color change layer 24.

When the temperature of the light emitting unit 22 is less than or equal to the threshold temperature, an electrical potential of the second electrode 242 may be controlled to adjust strength of the electric field between the first electrode 241 and the second electrode 242, enabling the color change layer 24 to have the first transmittance rate, and the first transmittance rate may be in a range of 80% to 100%.

When the temperature of the light emitting unit 22 is greater than the threshold temperature, the electrical potential of the second electrode 242 may be controlled to adjust the strength of the electric field between the first electrode 241 and the second electrode 242, enabling the color change layer 24 to have the second transmittance rate, and the second transmittance rate may be in a range of 0 to 80%.

Specifically, a range of the threshold temperature may be the same as that in the above embodiments. When the temperature of the light emitting unit 22 is less than or equal to the threshold temperature, the light emitting efficiency of the light emitting unit 22 may decrease significantly, the strength of the electric field between the first electrode 241 and the second electrode 242 may be controlled to enable the transmittance rate of the color change layer 24 to be in the range of 80% to 100%, enabling a majority of the light at the edge of the light emitting unit 22 to enter the heating portion 25. In this way, the heating portion 25 may be heated up by light irradiation, and the generated heat may be transferred, through the glass substrate 21, to the light emitting unit 22 adjacent to the heating portion 25, such that the heating function for the light emitting units 22 may be achieved, such that the light emitting efficiency of the light emitting units 22 at low temperatures may be improved. Specifically, since the cathode electrode 223 serves as the first electrode 241, the first electrode 241 may need to keep an electrical potential of the cathode drive signal unchanged. Therefore, the electrical potential of the second electrode 242 may be controlled to adjust the strength and a direction of the electric field between the first electrode 241 and the second electrode 242, enabling the color change layer 24 to have the first transmittance rate as described above.

Similarly, when the temperature of the light emitting unit 22 is greater than the threshold temperature, the light emitting unit 22 may not need to be heated, the electrical potential of the second electrode 242 may be controlled to adjust the strength and the direction of the electric field between the first electrode 241 and the second electrode 242, enabling the color change layer 24 to have the second transmittance rate as described above.

Specifically, the light emitting carrier board 20 may further include a plurality of connecting electrodes 215, each of the plurality of connecting electrodes 215 may extend through a respective one of the plurality of heating portions 25 to contact and to be electrically connected to the second electrode 242. A side of each connecting electrode 215 near the driver substrate 10 may be electrically connected to the driver circuit layer 12, such that connection of an electric field control signal may be achieved, such that the electric potential of the second electrode 242 may be controlled.

A structure and a function of the color change layer 24 and the heating portions 25 of the present embodiment may be the same or similar to the structure and the function of the color change layer 24 and the heating portions 25 in the above embodiment, and a same technical effect may be realized, which may be referred to the above embodiment and will not be repeated herein.

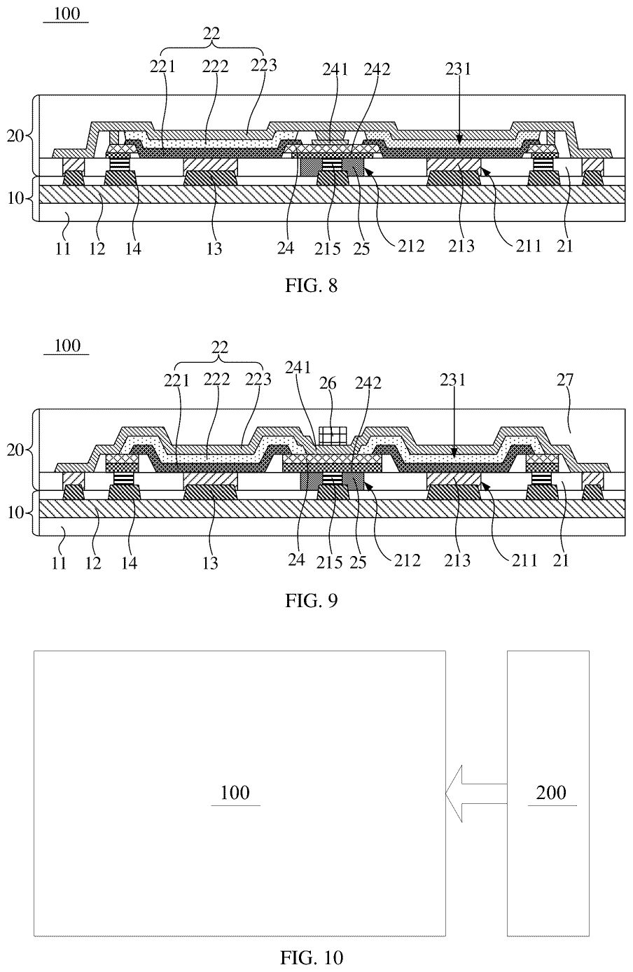

As shown in FIG. 8, FIG. 8 is a structural schematic view of the display panel according to a fifth embodiment of the present disclosure. Different from the embodiment shown in FIG. 7, in the present embodiment, in the direction perpendicular to the glass substrate 21, the two opposite sides of the color change layer 24 may be respectively arranged with the first electrode 241 and the second electrode 242. The first electrode 241 may be disposed on the side of the color change layer 24 near the cathode electrode 223, and the second electrode 242 may be disposed on the side of the color change layer 24 near the glass substrate 21. The color change layer 24 may change an optical state thereof based on the electric field formed by the first electrode 241 and the second electrode 242, enabling the transmittance rate of the color change layer 24 to be the same as that in the embodiment of FIG. 7.

Specifically, the first electrode 241 may be electrically connected to the cathode electrode 223. The second electrode 242 may be electrically connected to the driver circuit layer 12 via the respective connecting electrode 215. Each connecting electrode 215 may extend through one respective heating portion 25. Two opposite sides of the connecting electrode 215 in the thickness direction of the glass substrate 21 may be respectively electrically connected to the second electrode 242 and the driver circuit layer 12. The first electrode 241 may be electrically connected to the cathode electrode 223, such that a voltage drop of the cathode electrode 223 may be reduced, and signal homogeneity at various locations on the cathode electrode 223 may be improved. Since the electrical potential first electrode 241 may be the same as the electrical potential of the cathode electrode 223 and may maintain constant, the electrical potential of the second electrode 242 may be controlled to adjust the strength and the direction of the electric field between the first electrode 241 and the second electrode 242, so as to control the transmittance rate of the color change layer 24.

When the temperature of the light emitting unit 22 is less than or equal to the threshold temperature, the electrical potential of the second electrode 242 may be controlled to adjust the strength of the electric field between the first electrode 241 and the second electrode 242, enabling the color change layer 24 to have the first transmittance rate. The first transmittance rate may be in a range of 80% to 100%, such that function of heating the light emitting units 22 at low temperatures may be achieved, and the light emitting efficiency of the light emitting units 22 may be improved. Furthermore, since the material of the heating portions 25 may be the high entropy ceramic, the high entropy ceramic at the high temperature may be converted into the conductor, further improving signal stability of the second electrode 242.

When the temperature of the light emitting unit 22 is greater than the threshold temperature, the electrical potential of the second electrode 242 may be controlled to adjust the strength of the electric field between the first electrode 241 and the second electrode 242, enabling the color change layer 24 to have the second transmittance rate. The second transmittance rate may be in a range of 0 to 80%. Specifically, the second transmittance rate may be controlled to be below 50% to block the light at the edge of the light emitting unit 22 and reduce the influence by the light on the performance of the silicon-based driver member in the driver circuit layer 12.

As shown in FIG. 9, FIG. 9 is a structural schematic view of the display panel according to a sixth embodiment of the present disclosure. In the present embodiment, the light emitting carrier board 20 may further include a plurality of temperature sensors 26. Each of the plurality of temperature sensor 26 may be disposed between adjacent light emitting units 22 and may be configured to detect a current temperature of the light emitting unit 22, so as to control the electrical potential of the second electrode 242 based on the current temperature.

Specifically, the plurality of temperature sensors 26 may be uniformly distributed on the light emitting carrier board 20. The number and distribution of the plurality of temperature sensors 26 may be determined according to heating demands and the distribution of the plurality of heating portions 25. For example, when the light emitting carrier board 20 includes the plurality of heating zones that are spliced to each other, one of the plurality of temperature sensors 26 may be arranged in each of the plurality of heating zones and may detect a temperature of the respective heating zone, so as to control the electrical potential of the second electrode 242 based on the detected temperature, such that the transmittance rate of the color change layer 24 may be controlled. When the detected temperature is lower than the threshold temperature, a corresponding voltage signal may be transmitted to the second electrode 242 to adjust the strength and/or the direction of the electric field between the second electrode 242 and the first electrode 241, enabling the transmittance rate of the color change layer 24 to be in the range of 80% to 100%. The heating portion 25 may be heated under the light irradiation, so as to heat the light emitting units 22 arranged in the heating zone to improve the light emitting efficiency of the light emitting units 22. When the detected temperature is higher than the threshold temperature, another corresponding voltage signal may be transmitted to the second electrode 242, enabling the color change layer 24 to have a relatively low transmittance rate under a corresponding electric field between the first electrode 241 and the second electrode 242, and the relatively low transmittance rate may be less than 50%. The light at the edge of the light emitting units 22 may be blocked by the color change layer 24, and the influence by the light on the performance of the silicon-based driver member in the driver circuit layer 12 may be reduced.

Further, the light emitting carrier board 20 may further include an encapsulation layer 27, the encapsulation layer 27 may be arranged on a side of the cathode electrode 223 away from the glass substrate 21 and may be configured to encapsulate the plurality of light emitting units 22. The encapsulation layer 27 may achieve encapsulation by means of an inorganic encapsulation layer 27—an organic encapsulation layer 27—an inorganic encapsulation layer 27 that are stacked. Each temperature sensor 26 may be disposed between the cathode electrode 223 and the encapsulation layer 27 and may be located between adjacent light emitting units 22, such that the temperature sensor 26 may be prevented from blocking output light. Alternatively, the temperature sensor 26 may be arranged in another film layer, which may be determined according to the actual needs and will not be limited herein, as long as demands for temperature detection may be met, and the detected temperature of the light emitting units 22 may be closer to an actual temperature of the light emitting units.

As shown in FIG. 10, FIG. 10 is a structural schematic view of a display apparatus according to an embodiment of the present disclosure. In the present disclosure, a display apparatus is provided, the display apparatus may be arranged in a displaying technical field, such as in a pad, a mobile phone, a vehicle, VR glasses, an illuminating device, and the like.

The display apparatus may include the display panel 100 and a control circuit board 200. The control circuit board 200 may be electrically connected to the display panel 100 and may provide the display panel 100 with various drive signals, power signals, and other electrical signals required by the display panel 100, such that the control circuit board 200 may control the display panel 100 to display a corresponding image.

A specific structure and function of the display panel 100 in the present embodiment may be the same or similar to that of the display panel 100 in the above embodiments, and a same technical effect may be achieved, which may be referred to the description in the above.

When the display panel 100 in the embodiment of FIG. 9 above is applied herein, the control circuit board 200 may further be configured to obtain the temperature detected by the temperature sensor 26 and control the transmittance rate of the color change layer 24 based on the obtained detected temperature. Specifically, when the obtained detected temperature is lower than the threshold temperature, a corresponding voltage signal may be transmitted to the second electrode 242 to control the transmittance rate of the color change layer 24 to be in the range of 80% and 100%, enabling the heating portions 25 to be heated after irradiated by the light and to heat the light emitting units 22. When the obtained detected temperature is higher than the threshold temperature, another corresponding voltage signal may be transmitted to the second electrode 242, so as to control the transmittance rate of the color change layer 24 to be reduced, and the transmittance rate may be in the range of 0 and 80%. The light at the edge of the light emitting unit 22 may be blocked by the color change layer 24, such that the influence by the light on the performance of the silicon-based driver member in the driver circuit layer 12 may be reduced.

The above provides only embodiments of the present disclosure, and does limit the scope of the present disclosure. Any equivalent structure or equivalent process transformation performed based on the contents of the specification and the accompanying drawings of the present disclosure, applied directly or indirectly in other related technical fields, shall be equivalently included in the scope of the present disclosure.

What is claimed is:

1. A display panel, comprising:
a driver substrate, comprising a silicon substrate and a driver circuit layer arranged on the silicon substrate;
a light emitting carrier board, comprising:
a glass substrate, disposed on the driver substrate and having a plurality of electrode through holes;
a plurality of light emitting units, arranged into an array and arranged on a side of the glass substrate away from the driver substrate and electrically connected to a driver circuit layer through the plurality of electrode through holes;
wherein, the light emitting carrier board further comprises a color change layer and a plurality of heating portions; the color change layer is disposed between adjacent light emitting units of the plurality of light emitting units; the color change layer extends along a plane parallel to the glass substrate and contacts an edge of each of the plurality of light emitting units near the glass substrate; the glass substrate defines a plurality of heating through holes; an orthographic projection of the color change layer on the glass substrate covers the plurality of heating through holes; each of the plurality of heating portions fills a respective one of the plurality of heating through holes;
the color change layer has a first transmittance rate when a temperature of the plurality of light emitting units is less than or equal to a threshold temperature, the plurality of heating portions are configured to be heated under irradiation of light passing through the color change layer; and
the color change layer has a second transmittance rate when the temperature of the plurality of light emitting units is greater than the threshold temperature, the second transmittance rate is less than the first transmittance rate, and the color change layer is configured to block the light.

2. The display panel according to claim 1, wherein, the light emitting carrier board further comprises a pixel definition layer arranged on the glass substrate, the pixel definition layer defines a plurality of pixel openings that are in one-to-one correspondence with the plurality of light emitting units, orthographic projections of the pixel openings on the glass substrate cover the plurality of electrode through holes;
each of the plurality of light emitting units comprises an anode electrode, a light emitting layer, and a cathode electrode that are stacked and received in the respective pixel opening; the anode electrode is electrically connected to the driver circuit layer through the respective electrode through hole; the cathode electrode of one of the plurality of light emitting units and the cathode electrode of an adjacent one of the plurality of light emitting units are connected to each other and extend to an edge region of the glass substrate to be electrically connected to the driver circuit layer through a portion of the plurality of electrode through holes located at the edge region of the glass substrate;
the color change layer is disposed between adjacent pixel openings of the plurality of pixel openings and extends along a plane parallel to the glass substrate to contact and overlap with a side edge of the anode electrode near the glass substrate.

3. The display panel according to claim 2, wherein, the pixel definition layer further defines a function opening; the function opening exposes at least a portion of the color change layer; the anode electrode extends out of the respective pixel opening and extends into the function opening to contact and overlap the color change layer; the anode electrode is spaced from the cathode electrode by the light emitting layer;
or
the anode electrode extends to reach the edge of the color change layer to contact and overlap with a side of the edge of the color change layer away from the glass substrate; the pixel definition layer is arranged on the side of the color change layer away from the glass substrate, and the pixel opening exposes the anode electrode.

4. The display panel according to claim 3, wherein, the color change layer defines a plurality of hollow portions that are in one-to-one correspondence with the plurality of light emitting units; the plurality of light emitting units are disposed at positions corresponding to the plurality of hollow portions; a periphery edge of each of the plurality of light emitting units extends out of the respective hollow portion to be overlapped with the color change layer; an overlapping portion of the color change layer and the anode electrode has a width in a range of 0.5 μm to 1.5 μm.

5. The display panel according to claim 3, wherein, the light emitting carrier board further comprises an auxiliary electrode, the auxiliary electrode extends through at least one of the plurality of heating portions, the color change layer, and the pixel definition layer along a thickness direction of the glass substrate; the auxiliary electrode contacts and is electrically connected to the cathode electrode; a side of the auxiliary electrode near the driver substrate is electrically connected to the driver circuit layer.

6. The display panel according to claim 3, wherein, a material of the color change layer is a thermochromic material; when a temperature is less than or equal to the threshold temperature, the first transmittance rate is in a range of 80% to 100%; when the temperature is greater than the threshold temperature, the second transmittance rate is in a range of 0 to 80%; a decrease rate of the second transmittance rate gradually increases as the temperature increases.

7. The display panel according to claim 3, wherein, a material of the color change layer is an electrochromic material; the cathode electrode extends into the function opening and contacts the color change layer, the cathode electrode serves as a first electrode of the color change layer; a side of the color change layer near the glass substrate is arranged with a second electrode;
when the temperature of the plurality of light emitting units is less than or equal to the threshold temperature, strength of an electric field between the first electrode and the second electrode is adjusted by controlling an electrical potential of the second electrode, the color change layer has the first transmittance rate, the first transmittance rate is in a range of 80% to 100%;
when the temperature of the plurality of light emitting units is greater than the threshold temperature, the strength of the electric field between the first electrode and the second electrode is adjusted by controlling the electrical potential of the second electrode, the color change layer has the second transmittance rate, the second transmittance rate is in a range of 0 to 80%.

8. The display panel according to claim 7, wherein, the light emitting carrier board further comprises a connecting electrode and a temperature sensor;
the connecting electrode extends through at least one of the plurality of heating portions and contacts and is electrically connected to the second electrode; a side of the connecting electrode near the driver substrate is electrically connected to the driver circuit layer;
the temperature sensor is disposed between the adjacent light emitting units and is configured to detect a current temperature of the adjacent light emitting units to control the electrical potential of the second electrode based on the current temperature.

9. The display panel according to claim 1, wherein the color change layer has a thickness of 2000 Å to 3000 Å in a thickness direction of the glass substrate; a spacing between each of the plurality of heating through holes and one of the plurality of electrode through holes adjacent to the each heating through hole is not less than 2 μm; the threshold temperature is in a range of −40° C. to 0° C.; and a material of the plurality of heating portions is high entropy ceramic.

10. The display panel according to claim 1, wherein, a periphery of each of the plurality of light emitting units is arranged with at least one of the plurality of heating portions; and when the plurality of heating portions are heated under the light irradiation, each of the plurality of heating portions is configured to transfer heat to at least two of the plurality of light emitting units.

11. A display apparatus, comprising:
a display panel;
a control circuit board, electrically connected to the display panel and configured to control the display panel to display a corresponding image;
wherein the display panel, comprises: a driver substrate, comprising a silicon substrate and a driver circuit layer arranged on the silicon substrate; and a light emitting carrier board; the light emitting carrier board comprises:
a glass substrate, disposed on the driver substrate and having a plurality of electrode through holes;
a plurality of light emitting units, arranged into an array and arranged on a side of the glass substrate away from the driver substrate and electrically connected to a driver circuit layer through the plurality of electrode through holes;
wherein, the light emitting carrier board further comprises a color change layer and a plurality of heating portions; the color change layer is disposed between adjacent light emitting units of the plurality of light emitting units; the color change layer extends along a plane parallel to the glass substrate and contacts an edge of each of the plurality of light emitting units near the glass substrate; the glass substrate defines a plurality of heating through holes; an orthographic projection of the color change layer on the glass substrate covers the plurality of heating through holes; each of the plurality of heating portions fills a respective one of the plurality of heating through holes;
the color change layer has a first transmittance rate when a temperature of the plurality of light emitting units is less than or equal to a threshold temperature, the plurality of heating portions are configured to be heated under irradiation of light passing through the color change layer; and
the color change layer has a second transmittance rate when the temperature of the plurality of light emitting units is greater than the threshold temperature, the second transmittance rate is less than the first transmittance rate, and the color change layer is configured to block the light.

12. The display apparatus according to claim 11, wherein, the light emitting carrier board further comprises a pixel definition layer arranged on the glass substrate, the pixel definition layer defines a plurality of pixel openings that are in one-to-one correspondence with the plurality of light emitting units, orthographic projections of the pixel openings on the glass substrate cover the plurality of electrode through holes;
each of the plurality of light emitting units comprises an anode electrode, a light emitting layer, and a cathode electrode that are stacked and received in the respective pixel opening; the anode electrode is electrically connected to the driver circuit layer through the respective electrode through hole; the cathode electrode of one of the plurality of light emitting units and the cathode electrode of an adjacent one of the plurality of light emitting units are connected to each other and extend to an edge region of the glass substrate to be electrically connected to the driver circuit layer through a portion of the plurality of electrode through holes located at the edge region of the glass substrate;
the color change layer is disposed between adjacent pixel openings of the plurality of pixel openings and extends along a plane parallel to the glass substrate to contact and overlap with a side edge of the anode electrode near the glass substrate.

13. The display apparatus according to claim 12, wherein, the pixel definition layer further defines a function opening; the function opening exposes at least a portion of the color change layer; the anode electrode extends out of the respective pixel opening and extends into the function opening to contact and overlap the color change layer; the anode electrode is spaced from the cathode electrode by the light emitting layer;
or
the anode electrode extends to reach the edge of the color change layer to contact and overlap with a side of the edge of the color change layer away from the glass substrate; the pixel definition layer is arranged on the side of the color change layer away from the glass substrate, and the pixel opening exposes the anode electrode.

14. The display apparatus according to claim 13, wherein, the color change layer defines a plurality of hollow portions that are in one-to-one correspondence with the plurality of light emitting units; the plurality of light emitting units are disposed at positions corresponding to the plurality of hollow portions; a periphery edge of each of the plurality of light emitting units extends out of the respective hollow portion to be overlapped with the color change layer; an overlapping portion of the color change layer and the anode electrode has a width in a range of 0.5 μm to 1.5 μm.

15. The display apparatus according to claim 13, wherein, the light emitting carrier board further comprises an auxiliary electrode, the auxiliary electrode extends through at least one of the plurality of heating portions, the color change layer, and the pixel definition layer along a thickness direction of the glass substrate; the auxiliary electrode contacts and is electrically connected to the cathode electrode; a side of the auxiliary electrode near the driver substrate is electrically connected to the driver circuit layer.

16. The display apparatus according to claim 13, wherein, a material of the color change layer is a thermochromic material; when a temperature is less than or equal to the threshold temperature, the first transmittance rate is in a range of 80% to 100%; when the temperature is greater than the threshold temperature, the second transmittance rate is in a range of 0 to 80%; a decrease rate of the second transmittance rate gradually increases as the temperature increases.

17. The display apparatus according to claim 13, wherein, a material of the color change layer is an electrochromic material; the cathode electrode extends into the function opening and contacts the color change layer, the cathode electrode serves as a first electrode of the color change layer; a side of the color change layer near the glass substrate is arranged with a second electrode;
when the temperature of the plurality of light emitting units is less than or equal to the threshold temperature, strength of an electric field between the first electrode and the second electrode is adjusted by controlling an electrical potential of the second electrode, the color change layer has the first transmittance rate, the first transmittance rate is in a range of 80% to 100%;
when the temperature of the plurality of light emitting units is greater than the threshold temperature, the strength of the electric field between the first electrode and the second electrode is adjusted by controlling the electrical potential of the second electrode, the color change layer has the second transmittance rate, the second transmittance rate is in a range of 0 to 80%.

18. The display apparatus according to claim 17, wherein, the light emitting carrier board further comprises a connecting electrode and a temperature sensor;
the connecting electrode extends through at least one of the plurality of heating portions and contacts and is electrically connected to the second electrode; a side of the connecting electrode near the driver substrate is electrically connected to the driver circuit layer;
the temperature sensor is disposed between the adjacent light emitting units and is configured to detect a current temperature of the adjacent light emitting units to control the electrical potential of the second electrode based on the current temperature.

19. The display apparatus according to claim 11, wherein the color change layer has a thickness of 2000 Å to 3000 Å in a thickness direction of the glass substrate; a spacing between each of the plurality of heating through holes and one of the plurality of electrode through holes adjacent to the each heating through hole is not less than 2 μm; the threshold temperature is in a range of −40° C. to 0° C.; and a material of the plurality of heating portions is high entropy ceramic.

20. The display apparatus according to claim 11, wherein, a periphery of each of the plurality of light emitting units is arranged with at least one of the plurality of heating portions; and when the plurality of heating portions are heated under the light irradiation, each of the plurality of heating portions is configured to transfer heat to at least two of the plurality of light emitting units.
